(19) United States
(12) Patent Application Publication
(10) Pub. No.: US 2015/0333238 A1
(43) Pub. Date: Nov. 19, 2015

(54) PACKAGE STRUCTURE AND METHOD OF FABRICATING THE SAME

(71) Applicant: ACHROLUX INC., Sunnyvale, CA (US)

(72) Inventors: Peiching Ling, Sunnyvale, CA (US); Dezhong Liu, Sunnyvale, CA (US)

(21) Appl. No.: 14/715,959

(22) Filed: May 19, 2015

(30) Foreign Application Priority Data
May 19, 2014 (TW) 103117460

(51) Int. Cl. H01L 33/62; H01L 33/54; H01L 33/50

(52) U.S. Cl. CPC H01L 33/62; H01L 33/505; H01L 33/54; H01L 2933/0041; H01L 2933/005; H01L 2933/0066

(57) ABSTRACT

A package structure is provided, which includes a metal element, a light emitting element disposed on the metal element, an insulative body encapsulating the light emitting element, a conductive adhesive coupled to the light emitting element, and a phosphor layer covering the light emitting element and the conductive adhesive. By using the conductive adhesive as a circuit, the fabricating cost can be reduced for meeting the low-profile requirement. The present invention further provides a method of fabricating the package structure.

### BACKGROUND OF THE INVENTION

1. Field of the Invention

The present invention relates to package structures, and, more particularly, to a light emitting package.

2. Description of Related Art

With the advancement in electronic technology, the electronic devices have been developed in the direction of high functionality, high performance, and high speed. A light emitting diode (LED) has several advantages, including long life, small size, and high resistance to shock, and therefore has been widely used in various electronic products and household appliances.

FIG. 1 illustrates a cross-sectional diagram of a conventional LED package 1. The LED package 1 has a reflection cup 11 formed on a substrate 10. The reflection cup 11 has an opening 110, for an LED element 12 to be received therein. The LED element is electrically connected with the substrate 10 via a plurality of bonding wires 120 such as gold wires, and encapsulated by an encapsulant 13 having a phosphor layer.

However, in the conventional LED package 1, the bonding wires 120 are used to electrically connect the substrate 10 and the LED element 12. The higher reflection cup 11 is needed to accommodate the loop of the bonding wires 120, so as to completely encapsulate the bonding wires 120 by the encapsulant 13. As a result, the overall height of the LED package 1 cannot be reduced, and the low-profile requirement can not be met.

Moreover, the formation of bonding wires requires a wire bonding machine, and the price of the gold wires is expensive, whereby the total production cost of the LED package 1 is high.

Thus, there is an urgent need to solve the foregoing problems.

### SUMMARY OF THE INVENTION

In view of the foregoing problems, the present invention provides a package structure, comprising: a metal element; at least one light emitting element disposed on the metal element and having a non-active side coupled to the metal element and a light emitting side opposing the non-active side; an insulative body formed on the metal element for covering the light emitting element, and having a first surface from which the metal element is exposed and a second surface opposing the first surface; a conductive adhesive formed on the first surface of the insulative body and electrically connected to the light emitting side of the light emitting element; and a phosphor layer formed on the first surface of the insulative body and covering the light emitting side of the light emitting element and the conductive adhesive.

The present invention further provides a method of fabricating a package structure, comprising: coupling onto a metal element at least one light emitting element that has a non-active surface coupled to the metal element and an light emitting side opposing the non-active side; forming on the metal element an insulative body that covers the light emitting element and has a first surface from which the light emitting side of the light emitting element is exposed and a second surface opposing the first surface; forming on the first surface of the insulative body a conductive adhesive that is electrically connected to the light emitting side of the light emitting element; and forming on the first surface of the insulative body a phosphor layer that covers the light emitting side of the light emitting element and the conductive adhesive.

Accordingly, the package structure and the method for fabricating the same according to the present invention involve electrically connecting the conductive adhesive with the light emitting element, such that the conductive adhesive can be evenly applied on the first surface of the insulative body, and would not create a loop as in the conventional conductive wires. Through evenly applying the phosphor layer onto the first surface of the insulative body, the conductive adhesive can be covered, allowing the overall height of the package structure to be significantly reduced, thereby meeting the low-profile requirement.

Moreover, as the cost of using conductive adhesive is significantly lower than that of the conventional wire bonding method, the overall fabricating cost of the package structure can be significantly reduced.

### BRIEF DESCRIPTION OF DRAWINGS

The present invention can be fully understood by reading the following detailed description of the preferred embodiments, with reference made to the accompanying drawings, wherein:

FIG. 1 is a cross-sectional view of a conventional LED package;

FIGS. 2A-2F are cross-sectional views showing a method of fabricating a package structure according to the present invention; wherein FIG. 2A′ is the top view of FIG. 2A; and

FIGS. 3A-3F are cross-sectional views showing a method of fabricating a package structure according to the present invention.

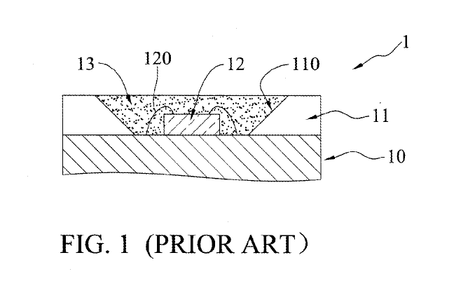

### DETAILED DESCRIPTION OF PREFERRED EMBODIMENTS

The present invention is described in the following with specific embodiments, so that one skilled in the pertinent art can easily understand other advantages and effects of the present invention from the disclosure of the present invention.

It should be noted that all the drawings are not intended to limit the present invention. Various modification and variations can be made without departing from the spirit of the present invention. Further, terms, such as “top”, “first”, “second”, “one”, etc., are merely for illustrative purpose and should not be construed to limit the scope of the present invention.

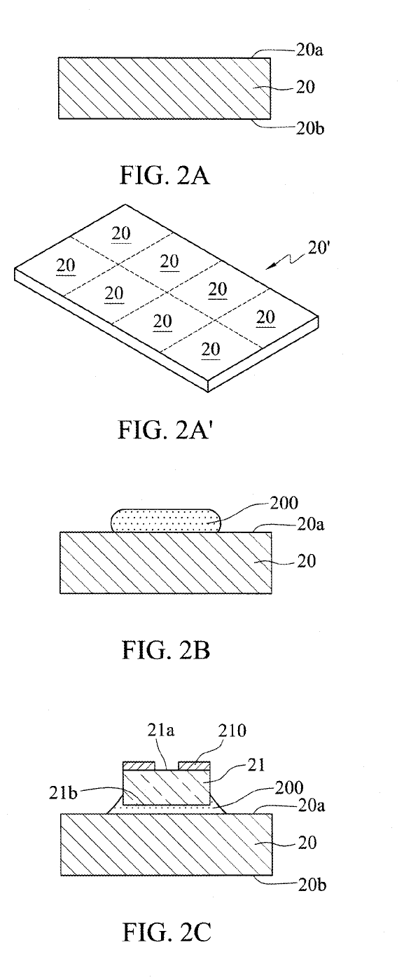

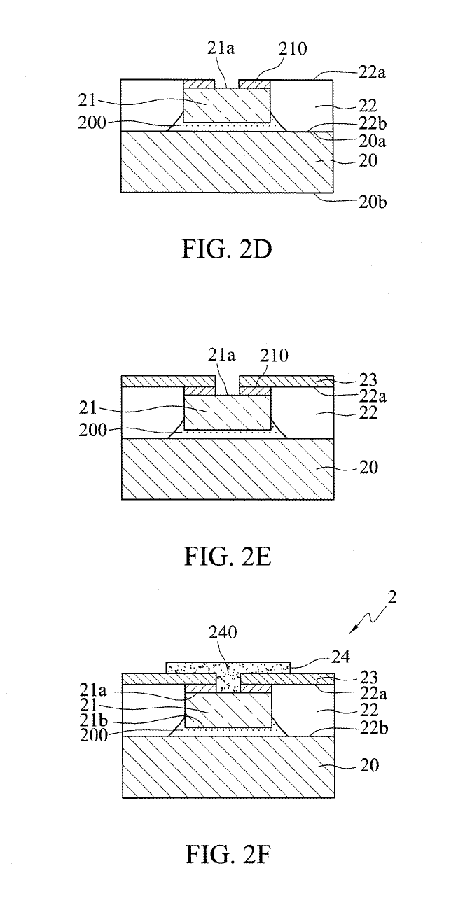

Referring to FIGS. 2A to 2F, schematic cross-sectional views showing a method of fabricating a package structure of a first embodiment according to the present invention are provided.

As shown in FIGS. 2A and 2A′, a board 20′ comprising a plurality of metal elements 20 is provided. The metal element 20 has a first side 20a and a second side 20b.

In an embodiment, the metal element 20 is made of aluminum and used as a heat dissipating board.

FIG. 2A is a partial cross-sectional view of FIG. 2A′. Since the fabricating process is the same for each of the metal elements 20, only one metal element 20 is shown in the drawing.

As shown in FIG. 2B, an adhesive material 200 is applied onto the first side 20a of the metal element 20 via a dispensing or coating method.

In an embodiment, the adhesive material 200 is a heat conductive material.

As shown in FIG. 2C, a plurality of light emitting elements 21 are disposed on the adhesive material 200 of the metal element 20. The light emitting elements 21 are disposed on the metal elements 20, respectively.

In an embodiment, the light emitting element 21 is a light emitting diode, and has a non-active side 21b coupled to the first side 20a of the metal element 20 and a light emitting side 21a opposing the non-active side 21b. The non-active side 21b acts as a heat dissipating side for the light emitting element 21.

As shown in FIG. 2D, an insulative body 22 is formed on the first side 20a of the metal element 20, and covers the light emitting element 21 and the adhesive 200, such that the first side 20a of the metal element 20 is completely covered, without being exposed.

In an embodiment, the insulative body 22 has a first surface 22a and a second surface 22b opposing the first surface 22a. The light emitting side 21a of the light emitting element 21 is exposed from the first surface 22a of the insulative body 22.

The surface of the electrodes 210 of the light emitting side 21a of the light emitting element 21 is flush with the first surface 22a of the insulative body 22.

The insulative body 22 is formed through, but not limited to, lamination, screen printing and stencil printing.

The insulative body 22 is made of, but not limited to, silicon or resin.

As shown in FIG. 2E, the conductive adhesive 23 is formed on the first surface 22a of the insulative body 22 and electrically connected with the electrodes 210 of the light emitting side 21a of the light emitting element 21.

In an embodiment, the conductive adhesive 23 acts as a circuit and can also dissipate heat. In another embodiment, the conductive adhesive 23 is a silver or copper adhesive, which can be easily applied to be formed on the surface, without the need of a wire bonding process, thereby simplifying the process (for instance, omitting the use of wire bonding machine) as well as reducing the cost (omitting the use of gold wires)

The conductive adhesive 23 is not in contact with the metal element 20.

As shown in FIG. 2F, a phosphor layer 24 having a plurality of phosphor particles 240 is formed on the first surface 22a of the insulative body 22 and covers the light emitting side 21a of the light emitting element 21 and a portion of the conductive adhesive 23.

In an embodiment, since the conductive adhesive 23 acts as a conductive element to connect with the light emitting element 21, without the need to consider the loop height of the conducive wires, the phosphor layer 24 could be made thinner, allowing the overall height of the package structure to be reduced.

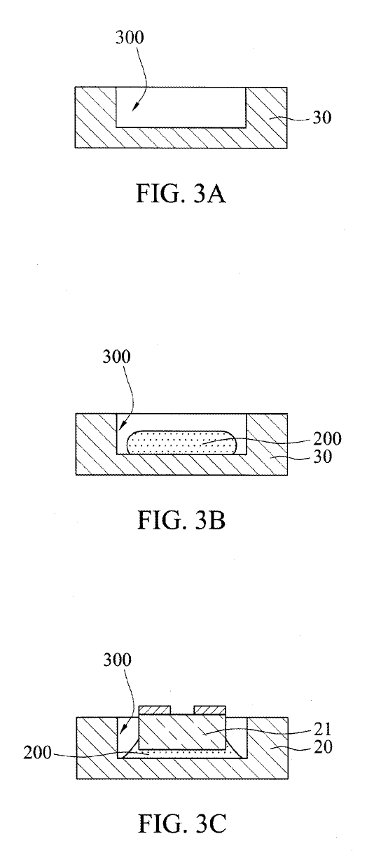

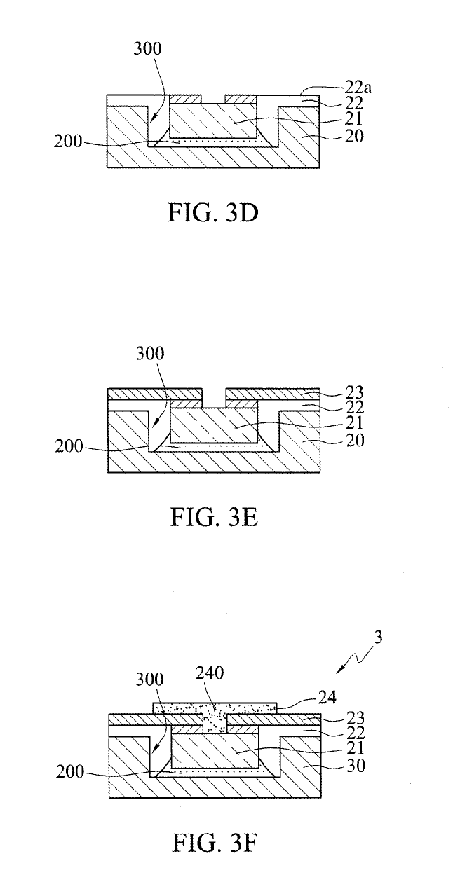

FIGS. 3A-3F are cross-sectional views showing a method of fabricating a package structure of a second embodiment according to present invention.

FIGS. 3A to 3C are similar to the processes shown in FIGS. 2A to 2C, except that the metal element 30 has an opening 300 for the light emitting element 21 to be received therein.

In an embodiment, the adhesive material 200 is formed in the opening 300.

FIGS. 3D to 3F are similar to the process shown in FIGS. 2D to 2F, except that the insulative body 22 is further formed in the opening 300. The first surface 22a of insulative body 22 is higher than the light emitting side 21a of the light emitting element 21, allowing the latter formed conductive adhesive 23 to be electrically connected with the electrodes 210 of the light emitting element 21.

In the first and second embodiments, the latter process includes forming a protective layer (not shown) such as a photic layer (not shown) for protecting the phosphor layer 24 on the phosphor layer 24, followed by a cutting process to form a plurality of light emitting packages 2.

The present invention has been described using exemplary preferred embodiments. However, it is to be understood that the scope of the present invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A package structure, comprising:
a metal element;
at least one light emitting element disposed on the metal element and having a non-active side coupled to the metal element and a light emitting side opposing the non-active side;
an insulative body formed on the metal element for covering the light emitting element, and having a first surface from which the metal element is exposed and a second surface opposing the first surface;
a conductive adhesive formed on the first surface of the insulative body and connected to the light emitting side of the light emitting element; and
a phosphor layer formed on the first surface of the insulative body and covering the light emitting side of the light emitting element and the conductive adhesive.

2. The package structure of claim 1, wherein the metal element has an opening, and the light emitting element is received in the opening.

3. The package structure of claim 1, wherein the light emitting element is coupled to the metal element via an adhesive material.

4. The package structure of claim 3, wherein the adhesive material is a conductive adhesive.

5. The package structure of claim 1, wherein the light emitting element is a light emitting diode.

6. The package structure of claim 1, wherein the conductive adhesive is a circuit.

7. A method of fabricating a package structure, comprising:
coupling onto a metal element at least one light emitting element that has a non-active surface coupled to the metal element and an light emitting side opposing the non-active side;
forming on the metal element an insulative body that covers the light emitting element and has a first surface from which the light emitting side of the light emitting element is exposed and a second surface opposing the first surface;
forming on the first surface of the insulative body a conductive adhesive that is electrically connected to the light emitting side of the light emitting element; and
forming on the first surface of the insulative body a phosphor layer that covers the light emitting side of the light emitting element and the conductive adhesive.

8. The method of claim 7, further comprising forming an opening in the metal element for receiving the light emitting element in the opening.

9. The method of claim 7, further comprising coupling the light emitting element onto the metal element via an adhesive material.

10. The method of claim 9, wherein the adhesive material is a conductive adhesive.

11. The method of claim 7, wherein the light emitting element is a light emitting diode.

12. The method of claim 7, wherein the conductive adhesive is a circuit.
